(19) United States
(12) Patent Application Publication
(10) Pub. No.: US 2025/0244496 A1
(43) Pub. Date: Jul. 31, 2025

(54) METHODS FOR MAGNETIC DATA ACQUISITION IN MARINE ENVIRONMENT

(71) Applicant: MARACQ AS, OPPDAL (NO)

(72) Inventor: Knut FOSTAD, Missouri City, MO (US)

(21) Appl. No.: 18/614,806

(22) PCT Filed: Nov. 25, 2022
(86) PCT No.: PCT/NO2022/050272

§ 371 Date: Mar. 25, 2024

(30) Foreign Application Priority Data
Nov. 30, 2021 (NO) 20211446

(51) Int. Cl. G01V 3/08; G01V 1/38; G01V 3/36

(52) U.S. Cl. CPC G01V 3/081; G01V 1/3843; G01V 3/36; G01V 2210/1293

(57) ABSTRACT

Methods for magnetic data acquisition in marine environment in parallel with towed streamer seismic data acquisition is provided. A method includes attaching at least one magnetometer/magnetic sensor with a buoy and positioning the magnetometer/magnetic sensor outside “prop wash” zone and/or far from sail line of the vessel so that removing noises in the magnetic data caused by movement of magnetometer and any other means of turbulence. Further, the buoy is equipped with a power generator and battery box to be self-sufficient with power to operate the magnetometer/magnetic sensor, and further comprises a radio link that communicate and transfer radio signal from the buoy to the vessel.

### TECHNICAL FIELD

The invention relates generally to the field of magnetic data acquisition in marine environment. More specifically, the invention relates to a method for acquiring, recording and transmitting magnetic data during marine geophysical surveys in parallel with multi streamer seismic data acquisition technique.

### BACKGROUND ART

Magnetic surveying is well established in land based mineral exploration. Typically, these surveys are done using an aircraft to map geology in covered terrains, to estimate the depth to basement in covered areas, and to identify altered zones, mineralization, bedding attitudes, and fault networks.

In the marine environments, particularly under the sea, magnetic surveys are being done using surface vessels or Automated Underwater Vehicles (AUVs) and Remotely Operated Vehicles (ROVs).

The magnetic data acquisitions in marine environment are used for a number of reasons; one of them is for UXO (Unexploded Ordnance) identification and location. UXO (Unexploded Ordnance) represents a hazard when laying pipelines on or below the bottom of the ocean, or when preparing foundation sites for offshore wind generators, anchors etc. In this case, typical target size is of less than a meter and typical depth of target (below ocean bottom) is 0 to a few meters.

Another reason is treasure hunting to identify different kinds of treasure and location e.g. parts of sunken ships or their cargo that might have magnetic properties. In this case, typical target size is of a few meters and typical depth of target (below ocean bottom) is 0 to 10.

Further, another reason is environmental surveys to identify shallow magnetic sediments.

Further another reason is for exploration geophysics that is used when searching for minerals or oil/gas. Obtaining best possible understanding of the sediment layers and reservoirs are important when identifying drilling targets in oil & gas exploration efforts. Further to map geology, to estimate the depth to basement, to identify altered zones, mineralization, bedding attitudes, and fault networks, various data are normally acquired, including seismic data, gravity data and magnetic data. Different sediment layers and different materials (e.g. salt, sand, and carbonate) have different magnetic properties, and hence magnetic data can bring important information in the complex process of creating models of the sub sea and identifying drilling prospects.

Though, the magnetic data acquisitions in marine environment are well known, typically magnetic data is acquired/recorded using one or more magnetometers (magnetic sensors) towed from a vessel. There are different manufacturers of magnetometers (magnetic sensors) such as tow fish in which a sensor is mounted, and where cables, additional electronics and software that makes it possible to record the data normally on a computer system.

Magnetic data acquisitions using single magnetic sensor measures the total magnetic intensity, which includes regional and local magnetic noise. So removing noise from measurement of total magnetic intensity, it is common to use readings from base station to obtain local readings.

Further, magnetic data acquisition using two magnetic sensors, in which magnetic gradient in one dimension is measured by subtracting the difference between the readings from two independent sensors. Since the Earth's magnetic field is three dimensional, up to three independent gradient directions can be measured. When using two magnetic sensors for magnetic gradiometer measurement in one direction, the distance between the magnetic sensors should be on the order of magnitude of expected depth from magnetometer sensors to target.

Magnetometers are also used by the military in magnetic mines to detect submarines. Consequently, some countries, such as the United States, Canada and Australia, classify the more sensitive magnetometers as military technology, and control their distribution.

Magnetometers can be used as metal detectors. They can detect only magnetic (ferrous) metals but can detect such metals at a much larger depth than conventional metal detectors, they are capable of detecting large objects, such as cars, ships, at tens of metres, while a metal detector's range is rarely more than 2 meters.

FIG. 1a to FIG. 1d illustrate magnetic data acquisition methods known in the prior art. FIG. 1a illustrates magnetic data acquisition method using a tow fish 10 containing one magnetic sensor 14, a pressure sensor 12 towed by a tow cable 16 that also include signal and power cables from the vessel.

FIG. 1b illustrates magnetic data acquisition method using an additional tow fish 10 containing another magnetic sensor 14 is towed from the back end of another tow fish 10. This method is also called longitudinal gradiometer. The distance between the sensors is determined by physical dimensions of tow fish 10 and length of cable 18 between the two fishes 10.

FIG. 1c and FIG. 1d illustrates magnetic data acquisition method using two tow fishes 10 are towed side by side on a horizontal plane and separated by fixed distance and held in place by gradiometer frame 20. This method is also called Horizontal gradiometer. In this case, magnetic sensor is towed by a tow cable 16 that also include signal and power cables from the vessel. Further the method provides two options, one option (FIG. 1c) is having only one tow cable 16 to the vessel, in which Y-split cable 22 is used that connects the two tow fishes 10 and another option (FIG. 1d) is having two tow cables 16. Known methods in the prior art are limited by utilizing tow cable 16 for powering the magnetic sensor (power supply from vessel) and for bringing measured signal back to the vessel (recorder on the vessel).

In addition to that a main challenge is of using tow cable from vessel (especially in parallel with multi streamer seismic data acquisition technique), there are physical and system limitations of such known methods (power and signal loss, cable dimension/strength).

Further, typical area in which magnetometer will be located, when towing magnetometer using tow cable from stern of vessel or using “gun tow”. Even if small cross line offset can be achieved using boom or similar, the magnetometer sensor will be towed in an area that are affected by turbulence from propeller wash and/or air gun arrays.

Further, magnetometer tow cable is fragile and no “wide tow” solution exists for this type of cable to be used in parallel with seismic data acquisition. In reality, magnetic data will only be sampled along vessel sail line or very close to it.

Thus, there is a long-felt need for a system and method to record magnetic data in parallel with towed streamer seismic data acquisition method. This invention provides attaching the magnetometer/magnetic sensor to a buoy far from a sail line and/or propeller wash. Further provides the buoy is specially equipped with a power generator (similar device like solar panels, wind turbine etc.) and battery box to be self-sufficient with power to operate magnetometers (magnetic sensors) and further comprises a radio link that communicate and transfer radio signal from the buoy to the vessel.

### SUMMARY OF INVENTION

Aspects of the present invention provide a method and system configuration to record magnetic data in parallel with towed streamer seismic data acquisition. A method includes attaching the magnetic sensor/magnetometer with a buoy far from a sail line or propeller wash, which means less turbulence and less magnetic noise in magnetic data.

In one aspect the invention provides a method for magnetic data acquisition in marine environment in parallel with towed streamer seismic data acquisition, comprising towing a plurality of seismic sources behind a survey vessel; towing a plurality of streamers coupled to a spreader line that connects to lead-ins connection; towing a buoy with the survey vessel, where the buoy is attached to the spreader line or to the lead-ins connection or to the streamers, and a tow cable towed behind the buoy is for attaching magnetometer/magnetic sensor. Where the buoy is equipped with a power generator (similar device like solar panels, wind turbine etc.) and battery box to be self-sufficient with power to operate the magnetometer/magnetic sensor, and further comprises a radio link that communicate and transfer radio signal from the buoy to the vessel.

The streamers are towed by means of their respective lead-ins (i.e. the high strength steel or fibre-reinforced electrical or electro-optical cables which convey electrical power, control and data signals between the vessel and the streamers), and their spread is controlled by two deflector devices, connected to the two outermost streamers. The deflector devices act in co-operation with respective spreader lines to maintain a substantially uniform spacing between the streamers.

In one aspect the magnetic data from the magnetometer/magnetic sensor is transmitted to a recorder on board of the seismic vessel by means of the radio link.

In one aspect the buoy is equipped with a power generator and battery box to power the magnetometer/magnetic sensor, signal transmission and signal recovery.

In another aspect, the invention provides a method for magnetic data acquisition in marine environment, comprising: towing a plurality of seismic sources behind a survey vessel; towing a plurality of streamers coupled to a spreader line that connects to lead-ins connection; towing a buoy with the survey vessel by attaching to the spreader line, to the lead-ins connection or to the streamers, and where a tow cable towed behind the buoy for attaching magnetometer/magnetic sensor, towing magnetometer/magnetic sensor attached with the buoy, and positioning the magnetometer/magnetic sensor outside “prop wash” zone and far from sail line of the vessel.

Other aspects and advantages of the invention will be apparent from the following description and the appended claims.

### BRIEF DESCRIPTION OF DRAWINGS

The detailed description will be better understood in conjunction with the accompanying drawings as follows:

FIG. 1a-FIG. 1d depict one or more magnetic sensor arrangements available for magnetic data acquisition in marine environment in the prior arts.

FIG. 2 depicts a method of magnetic data acquisition in marine environment in parallel with towed streamer seismic data acquisition according to an embodiment of the present invention.

FIG. 3 depicts a method of magnetic data acquisition in marine for a towing arrangement of typical four streamers configuration according to an embodiment of the present invention.

FIG. 4 depicts another method of magnetic data acquisition in marine environment for a towing arrangement of typical ten streamers configuration according to an embodiment of the present invention; and

FIG. 5 depicts a method of magnetic data acquisition in marine environment by positioning magnetometer/magnetic sensor far from the “prop wash” according to an embodiment of the present invention.

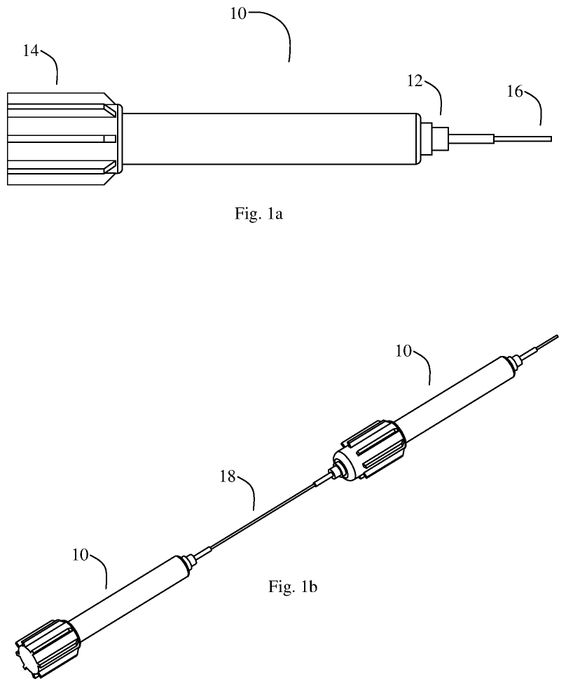

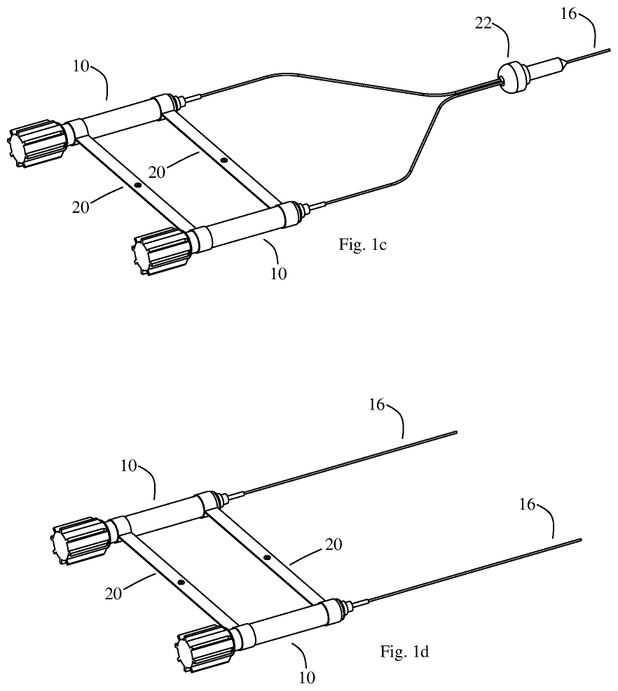

### DETAILED DESCRIPTION OF THE INVENTION

The present invention will now be described more fully hereinafter with reference to the accompanying drawings in which a preferred embodiment of the invention is shown. This invention may, however, be embodied in many different forms and should not be construed as being limited to the embodiments set forth herein. Rather, the embodiments are provided so that this disclosure will be thorough, and will fully convey the scope of the invention to those skilled in the art.

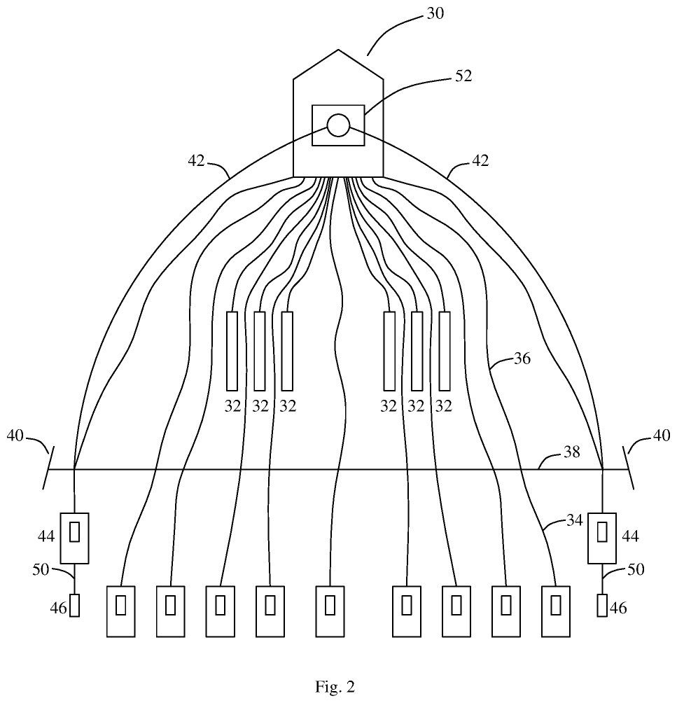

Embodiments of the invention provides new systems and methods for acquiring magnetic data in parallel with towed streamer seismic data acquisition. As shown in the FIG. 2, a seismic survey vessel 30 towing seismic sources 32, typically a multiple air gun source and an array of ten substantially identical streamers 34. However, it will be appreciated that, in practice, the streamers can be one or more than one without limiting the scope of the invention. The streamers 34 are towed by means of their respective lead-ins 36 (i.e. the high strength steel- or fibre-reinforced electrical or electro-optical cables which convey electrical power, control and data signals between the vessel 30 and the streamers 34), and their spread 38 is controlled by two deflector devices 40, connected to the two outermost streamers 34. The deflector devices 40 act in co-operation with respective spreader lines 38 to maintain a substantially uniform spacing between the streamers 34. Further a buoy 44 is towed behind the vessel 30 by attaching to the spreader line 38, to the lead-ins 36 connection or to the streamers 34, the buoy is specially equipped with a power generator (similar device like solar panels, wind turbine etc.) and battery box (Not shown in the figures) to be self-sufficient with power to operate magnetometers (magnetic sensors) 46 and further comprises a radio link 42 that communicate and transfer radio signal from the buoy 44 to the vessel 30.

In the alternative embodiments, the buoy 44 is attached to the deflector device 40 or can be towed from the deflector device 40.

In one embodiment, the buoy 44 is towed behind the vessel 30 by attaching to the spreader line 38, to the lead-ins 36 connection or to the streamers 34 and a tow cable 50 towed behind for attaching the magnetometer (magnetic sensor) 46. Where magnetic data from the magnetometer (magnetic sensor 46) is transmitted to a recorder 52 on board of the seismic vessel 30 by means of the radio link 42.

According to this configuration, the magnetometer 46 is towed in a better environment which means less turbulence and less magnetic noise in magnetic data as compared to high turbulence caused by movement of magnetometer 46 that causes noise in magnetic data.

Further with such configuration reduces operational problems as compared to prior art in which a magnetic cable in between seismic lead-ins and gun cables as well as in between gun floats and other seismic floats causes tangling breakage and damage and loss to equipment.

Further in another embodiment, the invention provides recording data from multiple magnetometer 46 in gradiometer configuration towed hundreds or thousands of meters apart. This is the key to recording magnetic gradiometer data with the objective of mapping magnetic properties of targets at depths in the hundreds or thousands of meters.

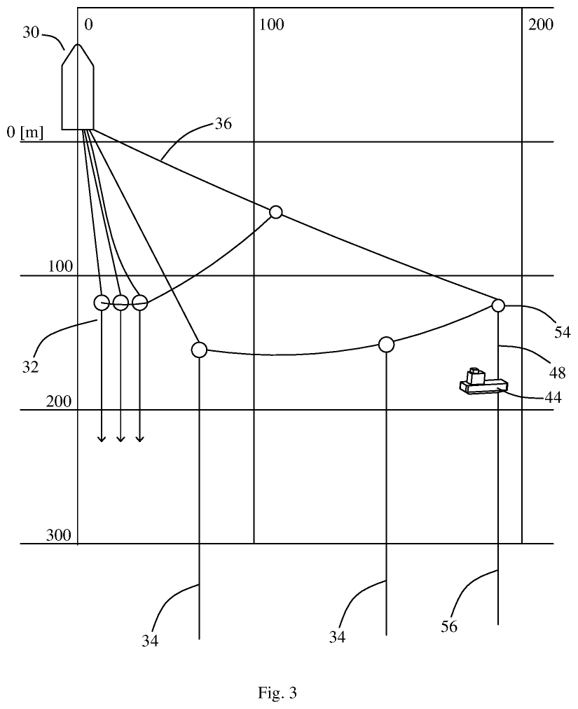

FIG. 3 illustrates a towing arrangement of typical four streamers 34 configuration. As shown in the FIG. 3 is one side of a towing arrangement of typical four streamers 34 configuration, where the seismic survey vessel 30 is towing seismic sources 32, typically a multiple air gun source and an array of two out of four substantially identical streamers 34 are shown. The streamers 34 are towed by means of their respective lead-ins 36, and their spread 38 is controlled by deflector device 40. Further, a buoy 44 is towed behind the vessel 30 46, the buoy 44 is specially equipped with a power generator and battery box to be self-sufficient with power to operate magnetometers 46 and further comprises a radio link 42 that communicate and transfer radio signal from the buoy 44 to the vessel 30.

Further a towing rope 48 is configured to attach the buoy 44 at a connection point 54. The buoy 44 is specially equipped with a power generator and battery box to ensure the buoy 44 is self-sufficient with power to operate magnetometer 46 and comprises a radio link 42 that communicate and transfer radio signal from the buoy 44 to the vessel 30.

In the embodiments, the buoy 44 comprises a towing rope 48 attaching to the spreader line 38, to the lead-ins 36 connection or to the streamers 34 and the magnetometer 46 is towed behind with a tow cable 50. Further magnetometer isolation transceiver and radio are mounted on the buoy 46. Where magnetic data from the magnetometer 46 is transmitted to recorder 52 on board of the seismic vessel 30 by means of radio link 42.

As shown in the FIG. 3, the magnetometer 46 is towed far from sail line of the vessel 30 at a position 56, which means less turbulence and less magnetic noise in magnetic data as compared to high turbulence caused by movement of magnetometer 46 that causes noise in magnetic data.

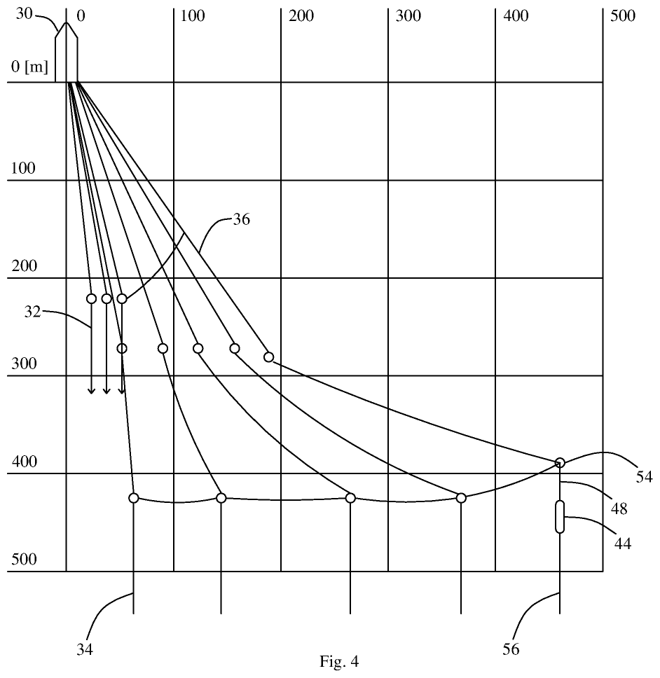

Similarly as shown in the FIG. 4 is another example of towing arrangement of typical ten streamers 34 configuration. As shown in the FIG. 4 is one side of a towing arrangement of typical ten streamers 34 configuration, where the seismic survey vessel 30 is towing seismic sources 32, typically a multiple air gun source and an array of five substantially identical streamers 34. Further a towing rope 48 is configured to attach the buoy 44 at a connection point 54 and the magnetometer 46 is towed behind with a tow cable 50. The buoy 44 is specially equipped with a power generator and battery box to ensure buoy is self-sufficient with power to operate magnetometer sensors 46 and comprises a radio link 42 that communicate and transfer radio signal from the buoy 44 to the vessel 30.

As shown in the FIG. 4, the magnetometer sensor 46 is towed far from sail line of the vessel 30 at a position 56, which means less turbulence and less magnetic noise is in magnetic data as compared to high turbulence caused by movement of magnetometer 46 and that causes noise in magnetic data.

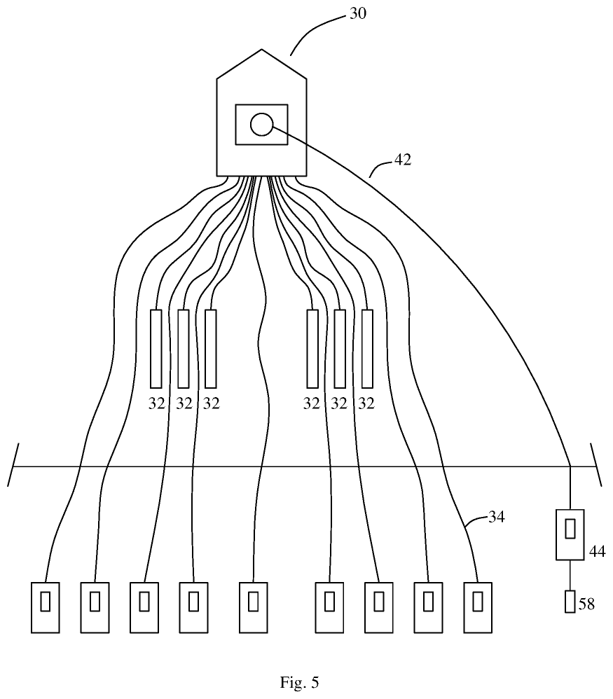

Further in traditional single sensor marine magnetic surveying, where a magnetometer (magnetic sensor) 46 is towed by a towing cable behind a vessel 30. In this traditional single sensor marine magnetic surveying “prop wash” can create noise in the magnetic data. Further the magnetic data from the single sensor is effected by “Diurnal variation”. Hence to overcome these mentioned problems, the invention proposed multiple magnetic sensors positioned outside “prop wash” zone as shown in FIG. 5.

In this embodiment, the magnetometer sensor 46 is positioned far from the “prop wash” with the buoy 44. The buoy 44 is specially equipped with a power generator and battery box to ensure buoy is self-sufficient with power to operate magnetometer sensors 46 and comprises a radio link 42 that communicate and transfer radio signal from the buoy 44 to the vessel 30.

As the buoy 44 is equipped with the radio link 42 so the magnetometer signal will no longer need cable for transmission back to reorder 52 on the vessel 30. The signal will be transferred to seismic vessel 30 by means of radio link 42. Radio link 42 between vessel 30 and buoy 44 allow location of magnetometer 46 independent of magnetometer tow cable 50 constraints.

As shown in the FIG. 5, the buoy 44 is towed far from sail line of the vessel 30 and the magnetometer is located at a position 58, which means less turbulence and less magnetic noise is in magnetic data as compared to high turbulence caused by movement of magnetometer 46.

The foregoing description of embodiments of the invention has been presented for purposes of illustration and description. It is not intended to be exhaustive or to limit the invention to the precise form disclosed, and modifications and variations are possible in light of the above teachings or may be acquired from practice of the invention without departing from the scope of the invention. The embodiments were chosen and described in order to explain the principles of the invention and its practical application to enable one skilled in the art to utilize the invention in various embodiments and with various modifications as are suited to the particular use contemplated.

1-13 (canceled)

14. A method for magnetic data acquisition in marine environment in parallel with towed streamer seismic data acquisition, comprising:
towing a plurality of seismic sources behind a survey vessel;
towing a plurality of streamers coupled to a spreader line that connects to lead-ins connection;
towing a buoy with the survey vessel, where the buoy comprises a towing rope for attaching at least to the spreader line or to the lead-ins connection or to the streamers and a tow cable towed behind for attaching magnetometer/magnetic sensor, wherein the buoy is equipped with a power generator and battery box to be self-sufficient with power to operate the magnetometer/magnetic sensor; and
further comprises a radio link that communicate and transfer radio signal from the buoy to the vessel.

15. The method according to claim 14, wherein magnetic data from the magnetometer/magnetic sensor is transmitted to a recorder on board of the seismic vessel by means of the radio link.

16. The method according to claim 14, wherein the buoy is equipped with the power generator and battery box to power the magnetometer/magnetic sensor, signal transmission and signal recovery.

17. The method according to claim 14, wherein the magnetometer/magnetic sensor is towed far from sail line of the vessel which means less turbulence and less or no magnetic noise in the magnetic data.

18. The method according to claim 14, wherein the magnetic data comprises less or no magnetic noise.

19. The method according to claim 14, wherein the magnetometer/magnetic sensor is attached with the buoy and positioned far from a prop wash zone.

20. A method for magnetic data acquisition in marine environment, comprising:
towing a plurality of seismic sources behind a survey vessel;
towing a plurality of streamers coupled to a spreader line that connects to lead-ins connection;
towing a buoy with the survey vessel, where the buoy comprises a towing rope for attaching at least to the spreader line or to the lead-ins connection or to the streamers and a tow cable towed behind for attaching magnetometer/magnetic sensor;
towing magnetometer/magnetic sensor attached with the buoy; and
positioning the magnetometer/magnetic sensor outside s prop wash zone and/or far from sail line of the vessel.

21. The method according to claim 20, wherein the buoy is equipped with a power generator and battery box to be self-sufficient with power to operate the magnetometer/magnetic sensor.

22. The method according to claim 20, wherein the buoy further comprises a radio link that communicate and transfer radio signal from the buoy to the vessel.

23. The method according to claim 20, wherein magnetic data from the magnetometer/magnetic sensor is transmitted to a recorder on board of the seismic vessel by means of the radio link.

24. The method according to claim 20, the magnetometer/magnetic sensor is towed far from sail line of the vessel which means less turbulence and less or no magnetic noise in the magnetic data.

25. The method according to claim 20, wherein the magnetic data comprises less or magnetic noise.

26. The method according to claim 20, wherein the method further provides recording data from multiple magnetometer in gradiometer configuration towed hundreds or thousands of meters apart and recording magnetic gradiometer data with the objective of mapping magnetic properties of targets at depths in the hundreds or thousands of meters
